(19) United States
(12) Patent Application Publication
(10) Pub. No.: US 2025/0351337 A1
(43) Pub. Date: Nov. 13, 2025

(54) GATE STRUCTURES IN THREE-DIMENSIONAL SEMICONDUCTIVE DEVICES

(71) Applicant: Yangtze Memory Technologies Co., Ltd., Wuhan (CN)

(72) Inventors: Jie YAN, Wuhan (CN); Zhixian MENG, Wuhan (CN); Yanwei SHI, Wuhan (CN); Quan ZHANG, Wuhan (CN); Cheng CHEN, Wuhan (CN)

(21) Appl. No.: 18/743,033

(22) Filed: Jun. 13, 2024

(30) Foreign Application Priority Data
May 8, 2024 (CN) 202410567460.6

(51) Int. Cl. H10B 12/00

(52) U.S. Cl. CPC H10B 12/50

(57) ABSTRACT

Devices and systems for gate structures in three-dimensional semiconductive devices are provided. In one aspect, a semiconductor device includes a first transistor, where the first transistor includes a source, a drain, and a gate structure. The gate structure includes a first region, and a second region protruding from a first corner of the first region along a first direction towards the source or the drain.

### CROSS-REFERENCE TO RELATED APPLICATIONS

This application claims priority to Chinese Patent Application No. 202410567460.6, filed on May 8, 2024, which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures.

### SUMMARY

The present disclosure describes methods, devices, systems and techniques for managing vertical structures in three-dimensional (3D) semiconductor devices.

One aspect of the present disclosure features a semiconductor device including a first transistor, where the first transistor includes a source, a drain, and a gate structure, and where the gate structure includes a first region; and a second region protruding from a first corner of the first region along a first direction towards the source or the drain.

In some implementations, the first direction is on a line connecting the source and the drain.

In some implementations, the first transistor includes a channel structure, the gate structure is in between the source and the drain, and the channel structure is on the gate structure on a vertical direction perpendicular to the first direction.

In some implementations, the first transistor includes a channel structure, and the gate structure is wider than the channel structure on a second direction perpendicular to the first direction.

In some implementations, a first distance is on the second direction and is from an edge of the channel structure to a point on border of the second region, a second distance is on the second direction and is from the edge of the channel structure to a point on border of the first region, and the first distance is greater than the second distance.

In some implementations, a first distance is on the first direction and is between two points on border of the first region, a second distance is on the first direction and is between a point on the border of the first region and a point on the border of the second region, and the first distance is smaller than the second distance.

In some implementations, the second region protrudes from the first corner of the first region along a second direction perpendicular to the first direction.

In some implementations, the gate structure includes a third region protruding from a second corner of the first region.

In some implementations, the second corner is diagonally positioned in relation to the first corner.

In some implementations, the semiconductor device includes an additional gate structure next to the gate structure along a second direction perpendicular to the first direction, where the additional gate structure includes an additional first region and an additional second region protruding from a first corner of the additional first region, and where the first corner of the first region and the first corner of the additional first region are positioned along the second direction.

In some implementations, the first corner and the second corner are on a same edge of the first region.

In some implementations, the semiconductor device includes an additional gate structure next to the gate structure along a second direction perpendicular to the first direction, where the additional gate structure includes an additional first region and an additional second region protruding from a first corner of the additional first region, and where the first corner of the first region and the first corner of the additional first region are positioned diagonally in relation to the first direction and the second direction.

In some implementations, the semiconductor device includes an additional gate structure next to the gate structure along the first direction, where the additional gate structure includes an additional first region and an additional second region protruding from a first corner of the additional first region, where a second corner of the first region is in between the first corner of the first region and the first corner of the additional first region along the first direction, and where no region protrudes from the second corner of the first region.

In some implementations, the semiconductor device includes a complementary metal-oxide-semiconductor (CMOS) device, and the first transistor is included in the CMOS device. In some implementations, the CMOS device is included in a page buffer.

Another aspect of the present disclosure features a mask for forming a gate structure, where the mask includes a first region; and a second region protruding from a first corner of the first region along a first direction towards a source or a drain associated with the gate structure.

In some implementations, the second region protrudes from the first corner of the first region along a second direction perpendicular to the first direction.

In some implementations, the mask includes a third region protruding from a second corner of the first region.

In some implementations, the second corner is diagonally positioned in relation to the first corner.

In some implementations, the mask is included in a layout, where the layout includes an additional mask next to the mask along a second direction perpendicular to the first direction, where the additional mask includes an additional first region and an additional second region protruding from a first corner of the additional first region, and where the first corner of the first region and the first corner of the additional first region are positioned along the second direction.

In some implementations, the first corner and the second corner are on a same edge of the first region.

In some implementations, the mask is included in a layout, where the layout includes an additional mask next to the mask along a second direction perpendicular to the first direction, where the additional mask includes an additional first region and an additional second region protruding from a first corner of the additional first region, and where the first corner of the first region and the first corner of the additional first region are positioned diagonally in relation to the first direction and the second direction.

In some implementations, the mask is included in a layout, where the layout includes an additional mask next to the mask along a second direction perpendicular to the first direction, where the additional mask includes an additional first region and an additional second region protruding from a first corner of the additional first region, where a second corner of the first region is in between the first corner of the first region and the first corner of the additional first region along the first direction, and where no region protrudes from the second corner of the first region.

A further aspect of the present disclosure features a system, including: a semiconductor device including a first transistor, where the first transistor includes a source, a drain, and a gate structure, and where the gate structure includes a first region; and a second region protruding from a first corner of the first region along a first direction towards the source or the drain; and a memory controller electrically connected to the semiconductor device, where the memory controller is configured to control the semiconductor device.

Implementations of the present disclosure can provide one or more of the following technical advantages and/or benefits. For example, in some cases, a gate structure having one or more protruding regions at one or more corners of the gate structure can be formed. The one or more protruding regions can enable to maintain a dimension of the gate structure greater than the channel length of the transistor having the gate structure, and thus avoid the leakage of the transistor. Moreover, in some cases, the fabrication of the gate structure does not involve removing the round-shaped area(s) at the edge(s) of the gate structure. Therefore, the fabrication cost of the gate structure can be reduced. Further, in some cases, by positioning two adjacent gate structures in a way that an inward corner of a gate structure is next to a protruding region of another gate structure, the two gate structures can be positioned close to each other while keeping a safe distance between the two gate structures. As a result, the density of active areas and thus the density of transistors on a semiconduction device can be increased.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a cross-sectional view of an example memory device.

FIG. 1B illustrates a cross-sectional view of another example memory device.

FIG. 2 illustrates a plain view of example layout of transistors in peripheral circuits of a memory device.

FIG. 3 depicts a cross-sectional view of a transistor along cut line AA′ shown in FIG. 2.

FIG. 4 depicts a three-dimensional view of the example layout of transistors shown in FIG. 2.

FIG. 5 illustrates a plain view of example layout of transistors in peripheral circuits of a memory device after removing the round-shaped areas of the gate structures.

FIG. 6 illustrates a plain view of an example transistor having an example gate structure having one or more protruding regions.

FIG. 7 illustrates a plain view of an example layout of transistors including gate structures having one or more protruding regions.

FIG. 8 illustrates a plain view of another example gate structure having one or more protruding regions.

FIG. 9 illustrates a plain view of an example layout of transistors including gate structures having one or more protruding regions.

FIG. 10 illustrates a plain view of a layout of two example masks for forming gate structures.

FIG. 11 illustrates an example mask and an example gate structure formed by using the mask based on a simulation result.

FIG. 12 illustrates a block diagram of a system having one or more semiconductor devices, according to one or more implementations of the present disclosure.

Like reference numbers and designations in the various drawings indicate like elements. It is also to be understood that the various exemplary implementations shown in the figures are merely illustrative representations and are not necessarily drawn to scale.

### DETAILED DESCRIPTION

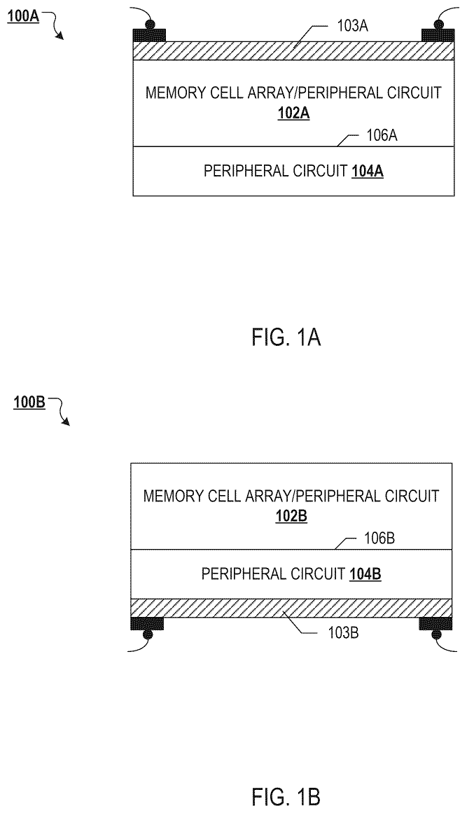

FIGS. 1A-1B illustrate cross-sectional views of example memory devices 100A and 100B. The memory devices 100A or the memory device 100B can represent an example of a memory device including the gate structures disclosed herein.

FIG. 1A illustrates a cross-sectional view of the example memory device 100A. As shown, the memory device 100A includes a first wafer 102A, a second wafer 104A, a pad-out interconnect layer 103A, and a boding interface 106A. In some implementations, at least some of the memory cell array and peripheral circuits of the memory device 100A are formed separately on different wafers (e.g., the first wafer 102A and the second wafer 104A) in parallel and then jointed to form a bonded structure.

The first wafer 102A can include an array of memory cells (also referred to herein as a “memory cell array”). In some implementations, each cell includes a capacitor for storing a bit of data as well as one or more transistors that control (e.g., switch and select) access to the cell. In some implementations, each memory cell is a one-transistor, one-capacitor (1T1C) cell.

As shown in FIG. 1A, the first wafer 102A can include at least some of the peripheral circuits of the memory device 100A. The second wafer 104A can include the remaining peripheral circuits of the memory device 100A. That is, the peripheral circuits of the memory device 100A can be separated into at least two wafers 102A and 104A, with some peripheral circuitry and the memory cell array integrated into first wafer 102A.

The peripheral circuits (also referred to herein as “control and sensing circuits”) can include any suitable digital, analog, and/or mixed-signal circuits used for facilitating the operations of the memory cell array. For example, the peripheral circuits can include one or more of a page buffer, a decoder (e.g., a row decoder and a column decoder), a sense amplifier, a driver (e.g., a word line driver), a data In/Out buffer, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in first and second wafers 102A and 104A can use, for example, complementary metal-oxide-semiconductor (CMOS) technology, which can be implemented with logic processes in any suitable technology nodes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.).

In some cases, first wafer 102A and second wafer 104B are stacked in different planes. As a result, the memory cell array and peripheral circuits in first wafer 102A, and the peripheral circuits in second wafer 104A, can be stacked in different planes to reduce the planar size of memory device 100A, compared with memory devices in which all the peripheral circuits are disposed in the same plane.

As shown in FIG. 1A, the bonding interface 106A is between first wafer 102A and second wafer 104A. Bonding interface 106A can be an interface between two semiconductor wafers formed by any suitable bonding technologies, such as hybrid bonding. In some implementations, bonding interface 106A is the place at which bonding layers are met and bonded. In some cases, bonding interface 106A can be a layer with a certain thickness that includes the bottom surface of bonding layer of first wafer 102A and the top surface of bonding layer of second wafer 104A.

First wafer 102A and second wafer 104A can be fabricated separately (and in parallel in some implementations), such that the thermal budget of fabricating one of first wafer 102A and second wafer 104A does not limit the processes of fabricating another one of first wafer 102A and second wafer 104A. Moreover, a large number of interconnects (e.g., bonding contacts) can be formed across bonding interface 106A to make direct, short-distance (e.g., micron-level) electrical connections between wafers 102A and 104A, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer among the memory cell array and the different peripheral circuits in first and second wafers 102A and 104A can be performed through the interconnects (e.g., bonding contacts) across bonding interface 106A. By vertically integrating first and second wafers 102A and 104A, the chip size can be reduced and the memory cell density can be increased. In some implementations, the pad-out interconnect layer 103A can be used for pad-out purposes, such as interconnecting with external devices using contact pads on which bonding wires can be soldered.

FIG. 1B illustrates a cross-sectional view of the example memory device 100B. Similar to the example memory device 100A, the example memory device 100B includes a first wafer 102B, a second wafer 104B, a pad-out interconnect layer 103B, and a boding interface 106B. Different from the example memory device 100A, the pad-out interconnect layer 103B is included in second wafer 104B that does not include the memory cell array. In other words, the pad-out interconnect layer can be arranged on either side of a memory device. The first wafer 102B, the second wafer 104B, the pad-out interconnect layer 103B, and the boding interface 106B can be structurally and/or functionally similar to the first wafer 102A, the second wafer 104A, the pad-out interconnect layer 103A, and the boding interface 106A, respectively, and the details are omitted here for brevity.

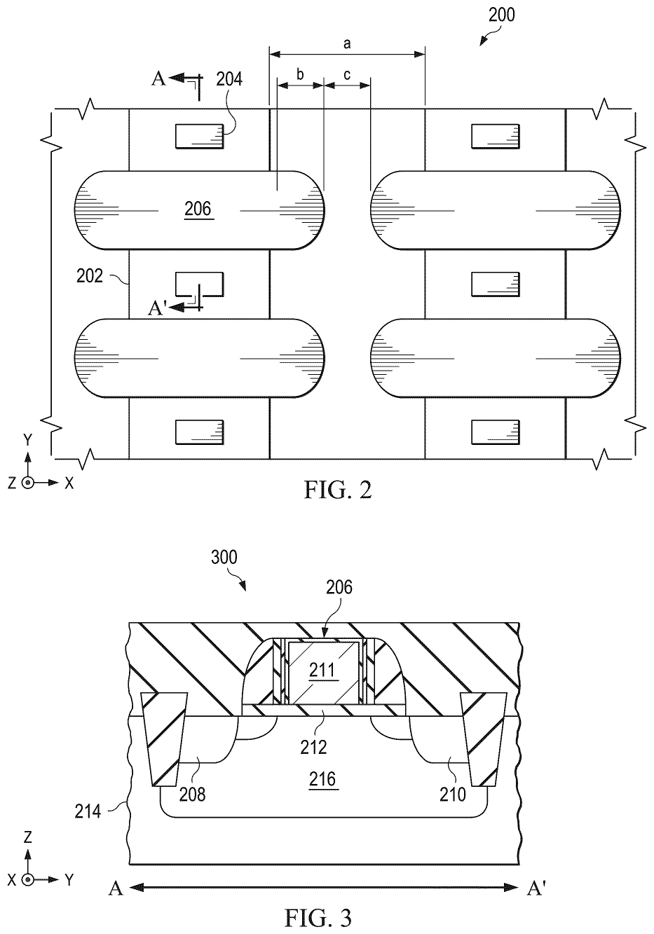

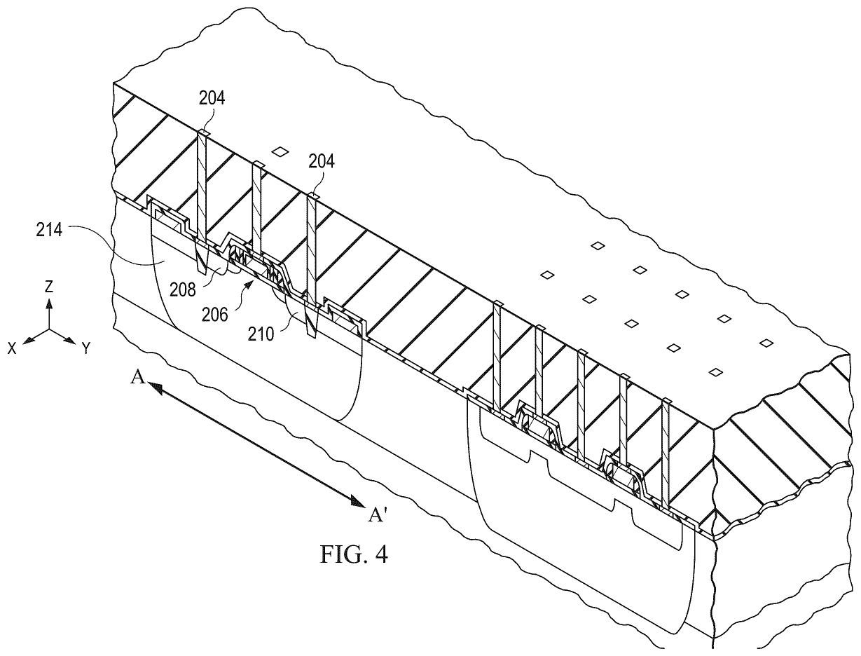

FIG. 2 illustrates a plain view of example layout 200 of transistors in peripheral circuits of a memory device. FIG. 3 depicts a cross-sectional view of a transistor 300 along cut line AA′ shown in FIG. 2. FIG. 4 depicts a three-dimensional view of the example layout 200 of transistors shown in FIG. 2. In some cases, the example layout 200 is in a CMOS device, such as a page buffer, in a wafer of peripheral circuits such as the second wafer 104A of FIG. 1A or the second wafer 104B of FIG. 1B.

As shown in FIG. 2, the example layout 200 includes active areas 202, gate structures 206, and contact structures 204. Each active area extends along a first direction (also referred to herein as “Y direction”). The active areas 202 can be positioned adjacent to each other along a second direction (also referred to herein as “X direction”) perpendicular to the first direction. An active area 202 includes a plurality of transistors (not shown in FIG. 2). As depicted in FIG. 3, in general, a transistor 300 includes a substrate 214, a well 216, a source 208, a drain 210, and a gate structure 206 arranged as shown. The source 208 and the drain 210 are formed in the well 216. The gate structure 206 can also be referred to as a gate. In some cases, the gate structure 206 is formed of a metallic gate electrode 211 and a gate dielectric 212 arranged as shown. A channel structure (not shown) is a portion of the well 216 between the source 208 and the drain 210. The channel structure can be formed under the gate structure 206 along a third direction (also referred to herein as “vertical direction” or “Z direction”) perpendicular to the Y direction and the X direction. For example, the channel structure can be formed on a side of the gate dielectric 212 opposite to the side of the metallic gate electrode 211. In some cases, the channel structure and the source 208 can form a gated PN diode. When this gated PN diode is reverse biased by applying a negative gate-to-source voltage (V_{GS}), a tunneling current occurs. As shown in FIG. 4, the contact structures 204 can extend along the Z direction and couple the transistors (e.g., the sources and/or the drains the of the transistors) to other components of the memory device.

As shown in FIG. 2, the two active areas 202 can be separated by a distance A along the X direction. Generally, decreasing the distance A can enable to increase the number of active areas that can be formed in a memory device. The increased number of active areas can result in an increased number of transistors that can be formed in a memory device, and thus can increase the density of transistors. The distance A can be limited by factors including the length B and distance C as shown in FIG. 2. The length B is a width of a round-shaped area along the X direction at the edge of the gate structure 206. The round-shaped area can be formed in the fabrication process of the gate structure 206. The distance C is the distance of two adjacent gate structures 206 along the X direction. For example, the distance C can be the distance between a rightmost point of a gate structure 206 and a leftmost point of another gate structure 206 along the X direction.

In some cases, the distance A needs to meet or exceed a sum of the length B and distance C. As shown, the distance A can be shorted by shortening the length B and/or shortening distance C. Shortening length B can be achieved by, for example, narrowing or even removing the round-shaped area. In some cases, shortening the distance C may not be achievable because the distance C needs to satisfy (e.g., meets or exceeds) a distance threshold to keep a safe distance of two adjacent gate structures. Some example gate structures that can shorten the distance A and thus increase the transistor density are discussed below.

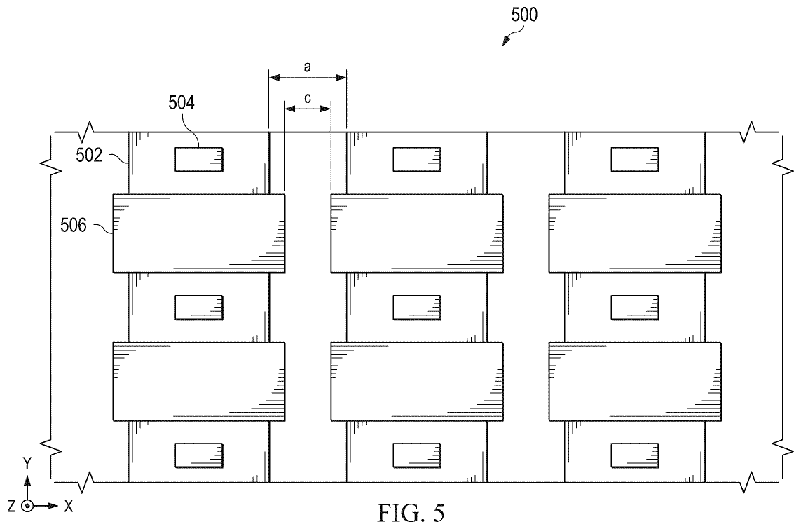

FIG. 5 illustrates a plain view of example layout 500 of transistors in peripheral circuits of a memory device after removing the round-shaped areas of the gate structures. The example layout 500 of transistors before removing the round-shaped areas of the gate structures can be structurally and/or functionally similar to the example layout 200 of transistors shown in FIG. 2.

Similar to the example layout 200 of transistors shown in FIG. 2, the example layout 500 of transistors includes active areas 502, gate structures 506, and contact structures 504. However, as shown in FIG. 5, the round-shaped areas of the gate structures 506 have been removed, as compared to the gate structures 206 of FIG. 2. As a result, the length B as shown in FIG. 2 is no longer shown in FIG. 5. Therefore, compared to FIG. 2, the distance A is limited by the distance C for example, the distance A needs to meet or exceed the distance C, instead of limited by both the length B and distance C as noted in FIG. 2. Without being limited by the length B, the distance A can be shortened, and the density of transistors can be increased.

In some implementations, the gate structures 506 having round-shaped areas can be formed first, and then the round-shaped areas of the gate structures 506 can be removed, for example, by using one or more masks. However, the additional step of removing the round-shaped areas of the gate structures 506 can increase the cost of fabricating the memory device.

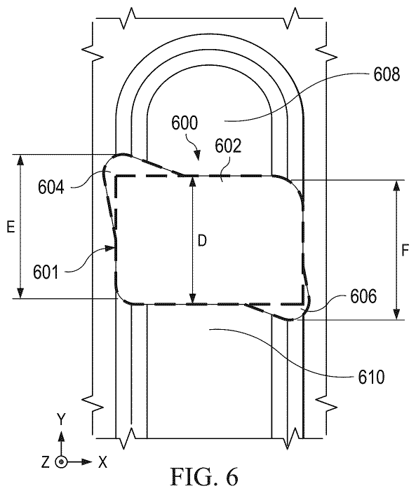

FIG. 6 illustrates a plain view of an example transistor 600 having an example gate structure 601 having one or more protruding regions. The example transistor 600 includes a source 608 (label shows the position of the source), a drain 610 (label shows the position of the drain), and the gate structure 601. The example transistor 600 can be structurally and/or functionally similar to the transistor 300 shown in FIG. 3, except that the gate structure 601 is different from the gate structure 206.

The gate structure 601 includes a first region 602, a second region 604 protruding from a first corner of the first region 602, and a third region 606 protruding from a second corner of the first region 602. The Y direction is on a line connecting the source and the drain. As shown, the second region 604 (or correspondingly, the first corner) is diagonally positioned in relation to the third region 606 (or correspondingly, the second corner). Although FIG. 6 depicts both the second region 604 and the third region 606, in some cases, the gate structure 601 includes only one of the second region 604 or the third region 606.

As shown, the second region 604 protrudes along the Y direction towards the source 608. The second region 604 also protrudes along the X direction. In some cases, the second region 604 protrudes along only one of the Y direction or the X direction.

Similarly, the third region 606 protrudes along the Y direction towards the drain 610. The third region 606 also protrudes along the X direction. In some cases, the third region 606 protrudes along only one of the Y direction or the X direction.

As shown, the distance D is on the Y direction and is between two points on border of the first region 602. The distance E is on the Y direction and is between a point on the border of the first region 602 and a point on the border of the second region 604. In some cases, the distance D is smaller than or equal to the distance E. This approach can prevent a leakage of the transistor 600 that may render the transistor 600 defective. Protruding from a corner of the first region 602 along the Y direction can extend the distance E, and can avoid the leakage problem.

The distance F is on the Y direction and is between a point on the border of the first region 602 and a point on the border of the third region 606. In some cases, the distance D is smaller than or equal to the distance F.

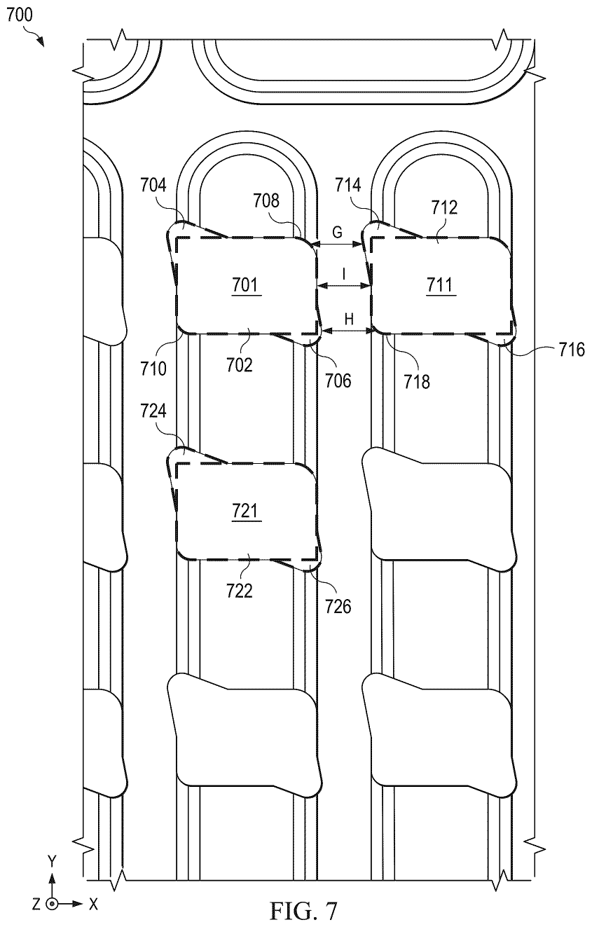

FIG. 7 illustrates a plain view of an example layout 700 of transistors including gate structures having one or more protruding regions. As shown in FIG. 7, arrays of gate structures are positioned along both the X direction and the Y direction, such as parallelly. In some cases, each gate structure in FIG. 7 is structurally and/or functionally similar to the gate structure 601 of FIG. 6.

Two gate structures 701 and 711 are adjacent to each other (e.g., in parallel) along the X direction. The gate structure 701 includes a first region 702, a second region 704 protruding from a first corner of the first region 702, and a third region 706 protruding from a second corner of the first region 702. Similarly, the gate structure 711 includes a first region 712, a second region 714 protruding from a first corner of the first region 712, and a third region 716 protruding from a second corner of the first region 712. As shown, the second region 704 of the gate structure 701 (or correspondingly, the first corner of the first region 702) and the second region 714 of the gate structure 711 (or correspondingly, the first corner of the first region 712) are positioned along the X direction. Similarly, the third region 706 of the gate structure 701 (or correspondingly, the second corner of the first region 702) and the third region 716 of the gate structure 711 (or correspondingly, the second corner of the first region 712) are positioned along the X direction.

As shown, the gate structure 701 has an inward corner 708, and the inward corner 708 is adjacent to the second region 714 of the gate structure 711. Distance G represents a distance, along the X direction, between a point of the inward corner 708 of the gate structure 701 and a point of the second region 714. Similarly, the gate structure 711 has an inward corner 718, and the inward corner 718 is adjacent to the third region 706 of the gate structure 701. Distance H represents a distance, along the X direction, between a point of the inward corner 718 of the gate structure 711 and a point of the third region 706 of the gate structure 701. Distance I represents a distance, along the X direction, between a point of the first region 702 of the gate structure 701 and a point of the first region 712 of the gate structure 711. In some cases, the distances G, I, and H are about the same.

By positioning two adjacent gate structures in a way that an inward corner of a gate structure is next to a protruding region of another gate structure, the two gate structures can be positioned close to each other while keeping a safe distance between the two gate structures. As a result, the density of active areas and thus the density of transistors on a semiconduction device can be increased.

Similar positioning can be applied to the Y direction. For example, a gate structure 721 is adjacent to the gate structure 701 (e.g., in parallel) along the Y direction. The gate structure 721 includes a first region 722, a second region 724 protruding from a first corner of the first region 722, and a third region 726 protruding from a second corner of the first region 722. As shown, along the Y direction, an inward corner 710 of the gate structure 701 is in between the second region 704 of the gate structure 701 (or correspondingly, the first corner of the first region 702) and the second region 724 of the gate structure 721 (or correspondingly, the first corner of the first region 722). No region protrudes from the inward corner 710 of the gate structure 701. Therefore, similar to the X direction, an inward corner of a gate structure can be next to a protruding region of another gate structure along the Y direction.

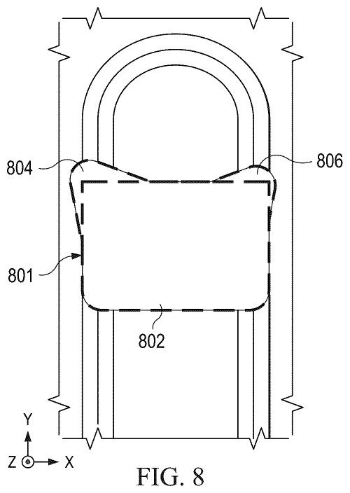

FIG. 8 illustrates a plain view of another example gate structure 801 having one or more protruding regions. As shown, the gate structure 801 includes a first region 802, a second region 804 protruding from a first corner of the first region 802, and a third region 806 protruding from a second corner of the first region 802. Although FIG. 8 depicts both the second region 804 and the third region 806, in some cases, the gate structure 801 includes only one of the second region 804 or the third region 806.

Compared to the gate structure 601 of FIG. 6, where the second region 604 is diagonally positioned in relation to the third region 606, the second region 804 and the third region 806 are on a same edge of the first region 802 in the gate structure 801 of FIG. 8. Except for this difference, the gate structure 801 can be structurally and/or functionally similar to the gate structure 601 shown in FIG. 6, and the details are omitted here for brevity.

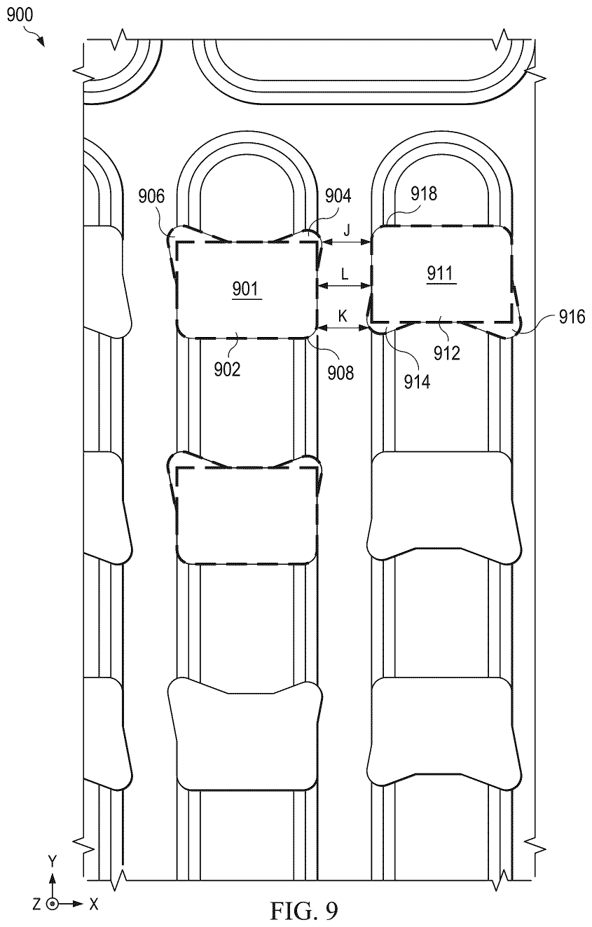

FIG. 9 illustrates a plain view of an example layout 900 of transistors including gate structures having one or more protruding regions. As shown in FIG. 9, arrays of gate structures are positioned along both the X direction and the Y direction, such as parallelly. In some cases, each gate structure in FIG. 9 is structurally and/or functionally similar to the gate structure 801 of FIG. 8.

Two gate structures 901 and 911 are adjacent to each other (e.g., in parallel) along the X direction. The gate structure 901 includes a first region 902, a second region 904 protruding from a first corner of the first region 902, and a third region 906 protruding from a second corner of the first region 902. Similarly, the gate structure 911 includes a first region 912, a second region 914 protruding from a first corner of the first region 912, and a third region 916 protruding from a second corner of the first region 912. As shown, the second region 904 (or correspondingly, the first corner of the first region 902) and the second region 914 (or correspondingly, the first corner of the first region 912) are positioned diagonally in relation to the X direction and the Y direction.

As shown, the gate structure 901 has an inward corner 908, and the inward corner 908 is adjacent to the second region 914 of the gate structure 911 along the X direction. Distance K represents a distance, along the X direction, between a point of the inward corner 908 of the gate structure 901 and a point of the second region 914. Similarly, the gate structure 911 has an inward corner 918, and the inward corner 918 is adjacent to the second region 904 of the gate structure 901 along the X direction. Distance J represents a distance, along the X direction, between a point of the inward corner 918 of the gate structure 911 and a point of the second region 904 of the gate structure 901. Distance L represents a distance, along the X direction, between a point of the first region 902 of the gate structure 901 and a point of the first region 912 of the gate structure 911. In some cases, the distances J, L, and K are about the same.

As noted and similar to the example layout 700 depicted in FIG. 7, by positioning two adjacent gate structures in a way that an inward corner of a gate structure is next to a protruding region of another gate structure, the two gate structures can be positioned close to each other while keeping a safe distance between the two gate structures. As a result, the density of active areas can be increased, and thus the density of transistors on a semiconduction device can be increased.

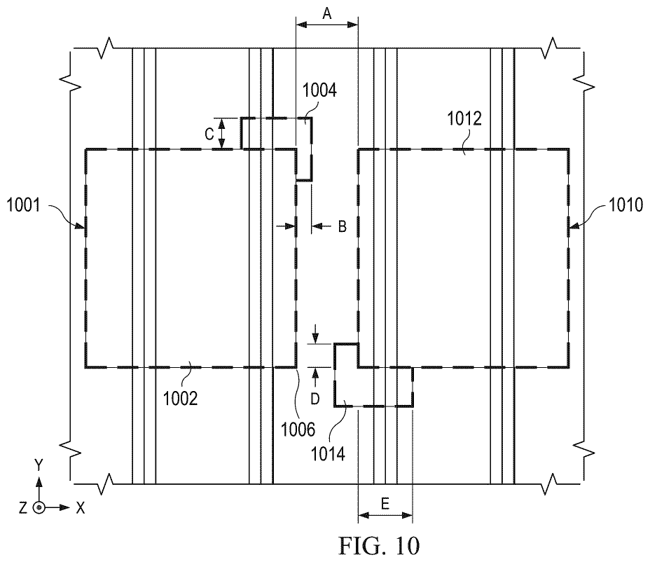

FIG. 10 illustrates a plain view of a layout of two example masks for forming gate structures. As shown, the layout includes the mask 1001 and the mask 1010 next to the mask 1001 along the X direction.

The mask 1001 includes a first region 1002 and a second region 1004 protruding from a first corner of the first region 1002. In some cases, the first region 1002 of the mask 1001 can be used to form, for example, the first region 602 of the gate structure 601 shown in FIG. 6 or the first region 802 of the gate structure 801 shown in FIG. 8. In some cases, the second region 1004 of the mask 1001 can be used to form, for example, the second region 604 of the gate structure 601, the third region 606 of the gate structure 601 shown in FIG. 6, the second region 804 of the gate structure 801, or the third region 806 of the gate structure 801 shown in FIG. 8.

As shown, the second region 1004 protrudes along the Y direction (e.g., a direction towards a source or a drain of a transistor having the gate structure formed by using the mask 1001). The second region 1004 also protrudes along the X direction. However, in some cases, the second region 1004 protrudes along only one of the X direction or the Y direction. While not shown in FIG. 10, in some implementations, the mask 1001 can include a third region protruding from a second corner of the first region 1002.

The mask 1010 includes a first region 1012 and a second region 1014 protruding from a first corner of the first region 1012. The layout including the masks 1001 and 1010 can be used to form, for example, the gate structures as depicted in layout 700 of FIG. 7 when two protruding regions of a gate structure are diagonally positioned. Alternatively, the layout including the masks 1001 and 1010 can be used to form, for example, the gate structures as depicted in layout 900 of FIG. 9 when two protruding regions of a gate structure are on the same edge.

More specifically, assume the case where two protruding regions of a gate structure are diagonally positioned (such as the gate structure 601 in FIG. 6). While not shown in FIG. 10, in some implementations, the mask 1010 can include a third region protruding from a second corner of the first region 1012, where the third region (or correspondingly, the second corner of the first region 1012) is diagonally positioned in relation to the second region 1014 (or correspondingly, the first corner of the first region 1012). The second region 1004 of the mask 1001 (or correspondingly, the first corner of the first region 1002) and the third region of the mask 1010 (or correspondingly, the second corner of the first region 1012) can be positioned along the X direction. Such layout can be used to form, for example, the gate structures as depicted in layout 700 of FIG. 7.

Alternatively, assume the case where two protruding regions of a gate structure are on the same edge. Under such case, in the layout including the mask 1001 and the mask 1010, the second region 1004 (or correspondingly, the first corner of the first region 1002) and the second region 1014 (or correspondingly, the first corner of the first region 1012) are positioned diagonally in relation to the X direction and the Y direction. Such layout can be used to form, for example, the gate structures as depicted in layout 900 of FIG. 9.

In some cases, while not shown, the layout can include an additional mask next to the mask 1001 along the Y direction. The additional mask can include an additional first region and an additional second region protruding from a first corner of the additional first region. A second corner 1006 of the first region 1002 of the mask 1001 is in between the second region 1004 of the mask 1001 (or correspondingly, the first corner of the first region 1002) and the additional second region of the additional mask (or correspondingly, the first corner of the additional first region) along the Y direction. No region protrudes from the second corner 1006 of the first region 1002 of the mask 1001.

Table I below shows example value ranges of the lengths A, B, C, D, and E shown in FIG. 10:

TABLE 1

| | A | B | C | D | E |
|---|---|---|---|---|---|
| Range (nm) | 40-90 | 8-24 | 10-40 | 20-50 | 20-50 |

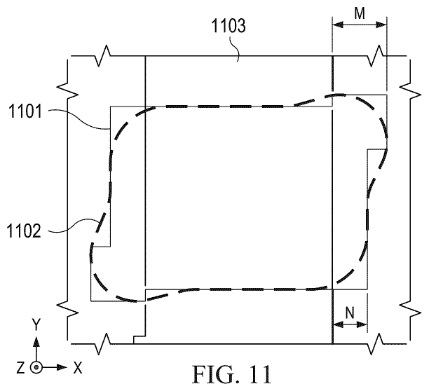

FIG. 11 illustrates an example mask 1101 and an example gate structure 1102 formed by using the mask 1101 based on a simulation result. The transistor having the gate structure 1102 can include a channel structure (not shown) that is narrower than or equal to the width of the active area 1103 along the X direction. In some cases, the gate structure 1102 is wider than the channel structure on the X direction.

As shown, the distance M is on the X direction and is from an edge of the active area 1103 (or an edge of the channel structure, if the width of the channel structure is equal to the width of the active area 1103 along the X direction) to a point on the border of the protruding region of the gate structure 1102. The distance N is on the X direction and is from an edge of the active area 1103 (or an edge of the channel structure, if the width of the channel structure is equal to the width of the active area 1103 along the X direction) to a point on the border of the gate structure 1102. In some cases, the distance M is greater than the distance N.

As can be seen from the descriptions above, the fabrication of the example gate structures described with respect to FIGS. 6-11 does not involve removing the round-shaped areas at the edges of the gate structures as described with respect to FIG. 5. Therefore, the cost of fabricating example gate structures described with respect to FIGS. 6-11 is lower than the cost of fabricating the example gate structure described with respect to FIG. 5, while the example gate structures described with respect to FIGS. 6-11 can still enable to increase transistor density similar to the example gate structure described with respect to FIG. 5.

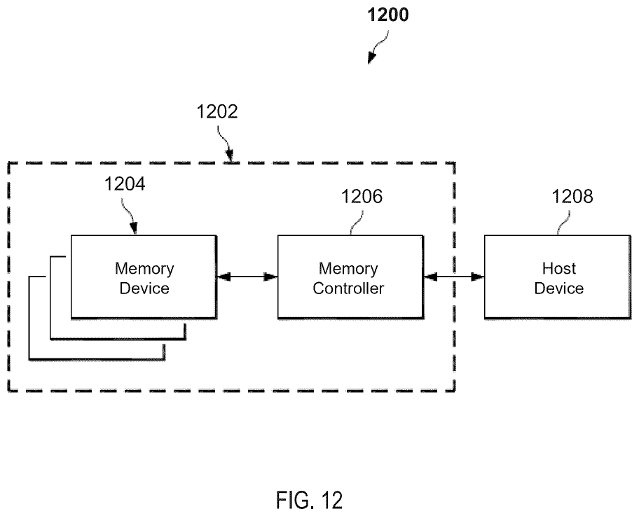

FIG. 12 illustrates a block diagram of a system 1200 having one or more semiconductor devices (e.g., memory devices), according to one or more implementations of the present disclosure. The system 1200 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 12, the system 1200 can include a host device 1208 and a memory system 1202 having one or more 3D memory devices 1204 and a memory controller 1206. Host device 1208 can include a processor of an electronic device, such as a central processing unit (CPU), or a system-on-chip (SoC), such as an application processor (AP). Host device 1208 can be configured to send or receive data to or from the one or more 3D memory devices 1204.

A 3D memory device 1204 can be any 3D memory device disclosed herein, such as 3D memory device depicted in FIGS. 1A-1B. In some implementations, a 3D memory device 1204 includes a NAND Flash memory. Memory controller 1206 (a.k.a., a controller circuit) is coupled to 3D memory device 1204 and host device 1208. Consistent with implementations of the present disclosure, 3D memory device 1204 can include a plurality of conductive interconnections through a cover layer that are in contact with conductive pads in a conductive pad layer, and memory controller 1206 can be coupled to 3D memory device 1204 through at least one of the plurality of conductive interconnections. Memory controller 1206 is configured to control 3D memory device 1204. For example, memory controller 1206 may be configured to operate a plurality of channel structures via word lines. Memory controller 1206 can manage data stored in 3D memory device 1204 and communicate with host device 1208.

In some implementations, memory controller 1206 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1206 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 1206 can be configured to control operations of 3D memory device 1204, such as read, erase, and program (or write) operations. Memory controller 1206 can also be configured to manage various functions with respect to the data stored or to be stored in 3D memory device 1204 including, but not limited to bad-block management, garbage collection, logical-to-physical address conversion, wear leveling, etc. In some implementations, memory controller 1206 is further configured to process error correction codes (ECCs) with respect to the data read from or written to 3D memory device 1204. Any other suitable functions may be performed by memory controller 1206 as well, for example, formatting 3D memory device 1204.

Memory controller 1206 can communicate with an external device (e.g., host device 1208) according to a particular communication protocol. For example, memory controller 1206 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1206 and one or more 3D memory devices 1204 can be integrated into various types of storage devices, for example, be included in the same package, such as a universal Flash storage (UFS) package or an eMMC package. That is, memory system 1202 can be implemented and packaged into different types of end electronic products. In one example as shown in FIG. 12, memory controller 1206 and a single 3D memory device 1204 may be integrated into a memory system 1202. Memory system 1202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device comprising a first transistor, wherein the first transistor comprises a source, a drain, and a gate structure, and wherein the gate structure comprises:
a first region; and
a second region protruding from a first corner of the first region along a first direction towards the source or the drain.

2. The semiconductor device of claim 1, wherein the first direction is on a line connecting the source and the drain.

3. The semiconductor device of claim 1, wherein the first transistor comprises a channel structure, the gate structure is in between the source and the drain, and the channel structure is on the gate structure on a vertical direction perpendicular to the first direction.

4. The semiconductor device of claim 1, wherein the first transistor comprises a channel structure, and the gate structure is wider than the channel structure on a second direction perpendicular to the first direction.

5. The semiconductor device of claim 4, wherein a first distance is on the second direction and is from an edge of the channel structure to a point on border of the second region, a second distance is on the second direction and is from the edge of the channel structure to a point on border of the first region, and the first distance is greater than the second distance.

6. The semiconductor device of claim 1, wherein a first distance is on the first direction and is between two points on border of the first region, a second distance is on the first direction and is between a point on the border of the first region and a point on the border of the second region, and the first distance is smaller than the second distance.

7. The semiconductor device of claim 1, wherein the second region protrudes from the first corner of the first region along a second direction perpendicular to the first direction.

8. The semiconductor device of claim 1, wherein the gate structure comprises a third region protruding from a second corner of the first region.

9. The semiconductor device of claim 8, wherein the second corner is diagonally positioned in relation to the first corner.

10. The semiconductor device of claim 9, comprising an additional gate structure next to the gate structure along a second direction perpendicular to the first direction, wherein the additional gate structure comprises an additional first region and an additional second region protruding from a first corner of the additional first region, and wherein the first corner of the first region and the first corner of the additional first region are positioned along the second direction.

11. The semiconductor device of claim 8, wherein the first corner and the second corner are on a same edge of the first region.

12. The semiconductor device of claim 11, comprising an additional gate structure next to the gate structure along a second direction perpendicular to the first direction, wherein the additional gate structure comprises an additional first region and an additional second region protruding from a first corner of the additional first region, and wherein the first corner of the first region and the first corner of the additional first region are positioned diagonally in relation to the first direction and the second direction.

13. The semiconductor device of claim 1, comprising an additional gate structure next to the gate structure along the first direction, wherein the additional gate structure comprises an additional first region and an additional second region protruding from a first corner of the additional first region, wherein a second corner of the first region is in between the first corner of the first region and the first corner of the additional first region along the first direction, and wherein no region protrudes from the second corner of the first region.

14. A mask for forming a gate structure, wherein the mask comprises:
a first region; and
a second region protruding from a first corner of the first region along a first direction towards a source or a drain associated with the gate structure.

15. The mask of claim 14, wherein the second region protrudes from the first corner of the first region along a second direction perpendicular to the first direction.

16. The mask of claim 14, wherein the mask comprises a third region protruding from a second corner of the first region.

17. The mask of claim 16, wherein the second corner is diagonally positioned in relation to the first corner.

18. The mask of claim 17, wherein the mask is comprised in a layout, wherein the layout comprises an additional mask next to the mask along a second direction perpendicular to the first direction, wherein the additional mask comprises an additional first region and an additional second region protruding from a first corner of the additional first region, and wherein the first corner of the first region and the first corner of the additional first region are positioned along the second direction.

19. The mask of claim 16, wherein the first corner and the second corner are on a same edge of the first region.

20. A system, comprising:
a semiconductor device comprising a first transistor, wherein the first transistor comprises a source, a drain, and a gate structure, and wherein the gate structure comprises:
a first region; and
a second region protruding from a first corner of the first region along a first direction towards the source or the drain; and
a memory controller electrically connected to the semiconductor device, wherein the memory controller is configured to control the semiconductor device.
